(19) United States
(12) Patent Application Publication
(10) Pub. No.: US 2010/0140661 A1
(43) Pub. Date: Jun. 10, 2010

(54) APPARATUS FOR CONVERTING OF INFRARED RADIATION INTO ELECTRICAL CURRENT

(76) Inventors: Gebhard Matt, Linz (AT); Thomas Fromherz, Rottenegg (AT)

Correspondence Address: COLLARD & ROE, P.C., 1077 NORTHERN BOULEVARD, ROSLYN, NY, 11576, US

(21) Appl. No.: 12/733,203

(22) PCT Filed: Aug. 23, 2007
(86) PCT No.: PCT/AT2007/000402

§ 371 Date: Feb. 17, 2010

(51) Int. Cl. H01L 51/46

(52) U.S. Cl. 257/184; 257/E51.038; 977/734

(57) ABSTRACT

An apparatus is described for converting infrared radiation into electric current with a photodiode which comprises two semiconductor layers (1, 2) with a heterojunction which are each connected to an electrode (3, 4) and of which one consists of a doped inorganic semiconductor. In order to ensure advantageous detection it is proposed that the inorganic semiconductor layer (1) forms the heterojunction with an organic semiconductor layer (2) and a cooling device is associated with the two semiconductor layers (1, 2).

An apparatus for converting infrared radiation into electric current

1. Field of the Invention

The invention relates to an apparatus for converting infrared radiation into electric current with a photodiode which comprises two semiconductor layers with a heterojunction which are each connected to an electrode and of which one consists of a doped inorganic semiconductor.

2. Description of the Prior Art

Photodiodes for converting infrared radiation into electric current are known in different embodiments. Indium-gallium-arsenide detectors are characterized for example by a comparatively high sensitivity in the infrared range, whereas platinum-silicide detectors are especially suitable for local resolution of infrared radiations in a two-dimensional arrangement, as is demanded in infrared cameras. The disadvantageous aspect in indium-gallium-arsenide detectors is especially the need for space, and in platinum-silicide detectors the low sensitivity.

### SUMMARY OF THE INVENTION

The invention is thus based on the object of arranging an apparatus of the kind mentioned above for converting infrared radiation into electric current in such a way that the requirements both concerning a compact two-dimensional arrangement and concerning high sensitivity can be combined with one another advantageously.

This object is achieved by the invention in such a way that the inorganic semi-conductor layer forms the heterojunction with an organic semiconductor layer and a cooling device is associated with the two semiconductor layers.

As a result of this measure, it is surprisingly possible to ensure a high sensitivity of the photocurrent in relation to the exciting radiation despite the simple compact configuration of the photodiode, especially in the middle infrared range, which is only possible however when the photodiode is cool in a respective fashion. Photodiodes with the heterojunction between an inorganic semiconductor and an organic semiconductor have already been proposed for photovoltaic purposes (JP 06244440 A). However, it is not possible to determine any dependence on infrared radiation for the photocurrent of these voltaic photodiodes. This is surprisingly only possible when the semiconductor layers are cooled. The photocurrent which is based on an absorption of the radiation in the infrared range will rise with increasing cooling and can be utilized for detecting infrared radiation. At room temperature, only the photocurrent is measured which is excited directly by the radiation absorption in the inorganic semiconductor layer and thus dependent on the band gap of the inorganic semiconductor, whereas at low temperatures the charge carriers excited by the infrared radiation pass increasingly from the valence band of the inorganic semiconductor to the conduction band organic semiconductor and from the bound state in the organic semiconductor into its conduction band and are discharged via the connected electrode as a result of the effective electric field.

Although different inorganic and organic semiconductors can be used for arranging a photodiode in accordance with the invention, since especially the relationship of the band gap of the doped inorganic semiconductor to the energy barrier between the valence band of the inorganic semiconductor and the conduction band of the organic semiconductor and the electronic structure of the organic semiconductor is relevant, especially simple constructional conditions are obtained when the inorganic semiconductor layer consists of a p-doped silicon layer which preferably forms a heterojunction with an organic semiconductor layer on the basis of a fullerene. If a fullerene derivative such as a soluble PCBM is used in this context as an organic semiconductor for example, the fullerene derivative can be applied in a spin coating as a thin film on a p-doped silicon substrate in a simple manner.

In order to cool the photodiode in accordance with the invention, different measures can be taken. If direct cooling is to be provided, the use of Peltier elements is recommended.

### BRIEF DESCRIPTION OF THE DRAWINGS

The subject matter of the invention is shown by way of example in the drawings, wherein:

FIG. 1 shows an apparatus in accordance with the invention for converting infrared radiation into electric current in a schematic sectional view, and

FIG. 2 shows the progression of the photocurrent depending on the excitation energy of the radiation at different temperatures.

### DESCRIPTION OF THE PREFERRED EMBODIMENTS

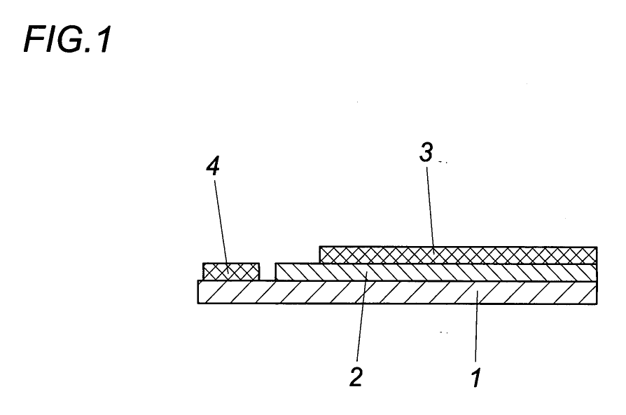

As can be seen from FIG. 1, the apparatus for converting infrared radiation into electric current comprises a photodiode which is composed of an inorganic semiconductor layer 1 and an organic semiconductor layer 2 which is applied to said semiconductor layer 1 by forming a heterojunction, with the two semiconductor layers 1 and 2 each being connected one electrode 3, 4. According to the chosen embodiment, the inorganic semiconductor layer 1 consists of a p-doped silicon substrate. This silicon substrate is doped with boron and has a charge carrier density of at least 1017 cm-3. A fullerene derivative, which is a soluble PCBM, is applied to this silicon substrate by spin coating with a thickness of approx. 150 nm. The electrodes 3 and 4 consist of aluminum and are evaporated with a thickness of approx. 100 nm onto the semiconductor layers 1 and 2. The photodiode can be cooled in a conventional manner by means of a Peltier element, which is not shown for reasons of clarity of the illustration. The illumination of the photodiode occurs from the side of the inorganic semiconductor layer 1. This means that the silicon substrate will become effective as a filter for the exciting radiation, so that the radiation range can be utilized only up to 1.2 eV due to the size of the band gap of the silicon. The detectable radiation is limited below by the electronic structure which is formed by the boundary layer between the inorganic semiconductor layer 1 and the used organic semiconductor layer 2. In the present case of a combination of silicon and fullerene, an ultimate energy of approx. 0.4 eV is obtained.

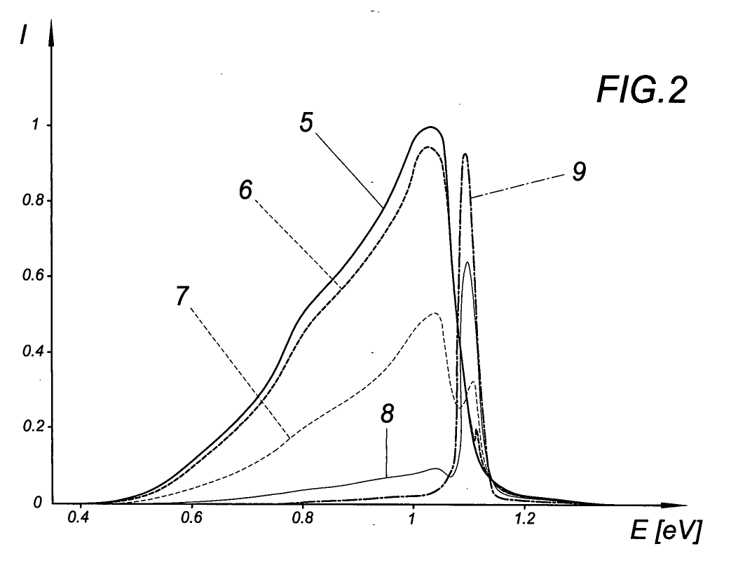

FIG. 2 shows the averaged photocurrent I depending on the radiation energy E, at different temperatures. Whereas the radiation energy is entered on the abscissa in eV, merely reference values to the maximum current are stated on the ordinate for the photocurrent. As is shown in the individual current curves, the progression of the photocurrent I depends on the respective temperature of the photodiode. Curve 5 therefore shows the progression of photocurrent at 13 K which is dependent on the excitation energy, and the curves 6, 7 and 8 the progression of photocurrent at 100 K, 150 K and 175 K. Curve 9 shows the progression of the photocurrent at 200 K. This illustration shows that the infrared range between 0.6 and 1 eV, which is especially interesting for many applications, can hardly be detected at 200 K because the photocurrent is small in this range according to curve 9 and hardly rises above the noise level. With decreasing temperature, the photocurrent which is excited by the infrared radiation increases disproportionately, as is illustrated by the curves 8 and 7 for a diode temperature of 175 K and 150 K. Excitation conditions which remain virtually the same can be assumed for decreasing temperature ranges from a diode temperature of 100 K (curve 6).

It is thus clear that following a cooling of the photodiode in accordance with the application the infrared range can be detected with a high sensitivity, which occurs with a simple diode configuration, preferably on a silicon substrate.

1. An apparatus for converting infrared radiation into electric current with a photodiode which comprises two semiconductor layers with a heterojunction which are each connected to an electrode (3, 4) and of which one consists of a doped inorganic semiconductor, wherein the inorganic semiconductor layer (1) forms the heterojunction with an organic semiconductor layer (2) and a cooling device is associated with the two semiconductor layers (1, 2).

2. An apparatus according to claim 1, wherein the inorganic semiconductor layer (1) consists of a p-doped silicon layer.

3. An apparatus according to claim 1, wherein the organic semiconductor layer (2) is arranged on the basis of a fullerene.

4. An apparatus according to claim 1, wherein the cooling device consists of a Peltier element.
